(19) United States
(12) Patent Application Publication
(10) Pub. No.: US 2025/0328405 A1
(43) Pub. Date: Oct. 23, 2025

(54) APPARATUS AND METHOD FOR FAULT DETECTION IN A DUAL CORE LOCKSTEP MICROCONTROLLER

(71) Applicant: Microchip Technology Incorporated, Chandler, AZ (US)

(72) Inventors: Erik Knutsen Renno, Trondheim (NO); Kjetil Kirkholt, Lensvik (NO); Asgeir Schanke, Hegra (NO)

(73) Assignee: Microchip Technology Incorporated, Chandler, AZ (US)

(21) Appl. No.: 19/186,884

(22) Filed: Apr. 23, 2025

Related U.S. Application Data
(60) Provisional application No. 63/637,770, filed on Apr. 23, 2024.

(51) Int. Cl. G06F 11/07; G01R 31/317

(52) U.S. Cl. CPC G06F 11/0772; G01R 31/31703; G06F 11/0724

(57) ABSTRACT

A method for fault detection in a dual core lockstep microcontroller is provided. The method may include executing a set of instructions by a first central processing circuitry, executing the set of instructions by one or more second central processing circuitries operating in parallel with the first central processing circuitry, comparing an output from the first central processing circuitry with an output from one or more second central processing circuitries using a first comparator, comparing the output from the first central processing circuitry with the output from the one or more second central processing circuitries using one or more second comparators, and triggering, by at least one logic gate, a fault signal in response to output signals received from the first comparator and the one or more second comparators.

### CROSS-REFERENCE TO RELATED APPLICATION

The present application claims priority from U.S. Provisional Patent Application No. 63/637,770 filed on Apr. 23, 2024, which is incorporated herein by reference in its entirety.

### TECHNICAL FIELD

The present disclosure relates generally to microcontrollers, and more specifically to an apparatus and method for performing fault detection in a dual core lockstep microcontroller.

### SUMMARY

According to an aspect of one or more examples, there is provided an apparatus for fault detection in a dual core lockstep microcontroller. The apparatus may include a first central processing circuitry to execute a set of instructions, one or more second central processing circuitry operating in parallel with the first central processing circuitry to execute the set of instructions, a first comparator to compare an output from the first central processing circuitry with an output from the one or more second central processing circuitries, one or more second comparators to compare the output from the first central processing circuitry with the output from the one or more second central processing circuitries and at least one logic gate to receive output signals from the first comparator and the one or more second comparators to trigger a fault signal based on the received output signals. The first central processing circuitry may include a first interrupt controller to receive an interrupt signal. The one or more second central processing circuitries may include one or more second interrupt controllers to receive the interrupt signal.

The apparatus may include a reset controller operatively coupled to receive the fault signal from the at least one logic gate. The reset controller may transmit a machine check reset signal responsive to the fault signal received from the at least one logic gate. The machine check reset signal may trigger a reset of the apparatus. The apparatus may include an error controller operatively coupled to receive the fault signal from the at least one logic gate. The error controller may transmit an input/output (IO) float signal responsive to the fault signal received from the at least one logic gate. The IO float signal may trigger an electrically floating state of one or more IO pins of the apparatus. The apparatus may include an error injection circuit operatively coupled to at least one of the one or more second comparators to selectively inject errors to modify or replace one or more of the output signals of the one or more second comparators to test the fault signal. The at least one logic gate may be an OR gate. The interrupt signal may be received by the first interrupt controller and the one or more second interrupt controllers in response to the machine check reset signal. The interrupt signal may be used to indicate that the fault signal has been triggered by the at least one logic gate.

According to an aspect of one or more examples, there is provided a method for fault detection in a dual core lockstep microcontroller. The method may include executing a set of instructions by a first central processing circuitry, executing the set of instructions by one or more second central processing circuitries operating in parallel with the first central processing circuitry, comparing an output from the first central processing circuitry with an output from one or more second central processing circuitries using a first comparator, comparing the output from the one or more second central processing circuitries using one or more second comparators and triggering a fault signal by at least one logic gate in response to output signals received from the first comparator and the one or more second comparators.

The method may include transmitting a machine check reset signal by a reset controller in response to the fault signal received from the at least one logic gate. The machine check reset signal may trigger a reset of the apparatus. The method may include transmitting an input/output (IO) float signal by an error controller in response to the fault signal received from the at least one logic gate. The IO float signal may trigger an electrically floating state of one or more IO pins of the apparatus. The method may include selectively injecting errors by an error injection circuit to modify or replace one or more of the output signals of the one or more second comparators to test the fault signal. The at least one logic gate may be an OR gate. The method may include receiving an interrupt signal by a first interrupt controller of the first central processing circuitry and one or more second interrupt controllers of the one or more second central processing circuitries in response to the machine check reset signal. The interrupt signal may be used to indicate that the fault signal has been triggered by the at least one logic gate.

### BRIEF DESCRIPTION OF DRAWINGS

FIG. 1 shows a block diagram illustrating an apparatus for fault detection in a dual core lockstep microcontroller according to one or more examples.

FIG. 2 shows a block diagram illustrating a method for fault detection in a dual core lockstep microcontroller according to one or more examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be embodied in various forms without being limited to the examples set forth herein.

Achieving a high degree of Functional Safety (FuSa) is important in safety-focused applications like automotive, industrial controls, medical devices, and aerospace systems. Functional safety ensures that systems relying on microcontrollers operate reliably even in the presence of faults or errors, or at least quickly detect faults or errors, thereby reducing the risk of hazards to users and the environment. These systems include a low fault detection time interval (FDTI) which represents the time taken to detect an error. The microcontrollers often use on software-based diagnostic self-tests to detect CPU errors. The software-based diagnostic self-tests consume valuable memory and CPU resources. The software-based diagnostic self-tests have limited diagnostic coverage and increased FDTI. For example, software diagnostics may detect less than 70% of CPU faults, and single software diagnostic implementation may not be able to detect timing-related errors without diverse implementation of the same diagnostic, which increases the demand for program memory space and decreases available CPU bandwidth. Therefore, there is a need for an improved apparatus and method for fault detection in the dual core lockstep microcontroller.

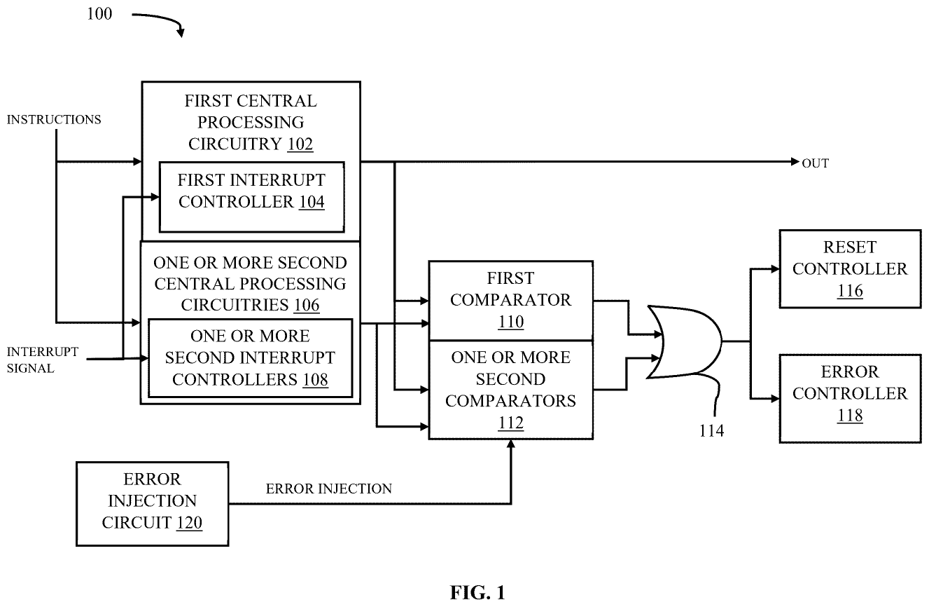

FIG. 1 shows a block diagram illustrating an apparatus 100 for detecting faults in a dual core lockstep microcontroller according to one or more examples. The apparatus 100 may include a first central processing circuitry 102, one or more second central processing circuitries 106, a first comparator 110, one or more second comparators 112, at least one logic gate 114, a reset controller 116, an error controller 118 and an error injection circuit 120.

The first central processing circuitry 102 and the one or more second central processing circuitries 106 may be in a lockstep mode, where the first central processing circuitry 102 and the one or more second central processing circuitries 106 execute a set of instructions. The one or more second central processing circuitries 106 may operate in parallel with the first central processing circuitry 102 so that the first central processing circuitry 102 and the one or more second central processing circuitries 106 execute the same set of instructions simultaneously or with a time offset. The first central processing circuitry 102 may include a first interrupt controller 104 to receive an interrupt signal. The one or more central processing circuitries 106 may include one or more second interrupt controllers 108 to receive the interrupt signal.

The first interrupt controller 104 and the one or more second interrupt controllers 108 may handle internal and/or external interrupts for the first central processing circuitry 102 and the one or more second central processing circuitries 106, respectively. The first interrupt controller 104 and the one or more second interrupt controllers 108 may respectively provide the first central processing circuitry 102 and the one or more central processing circuitries 106 with one or more interrupt signals to generate interrupts with different priority levels. The first interrupt controller 104 and the one or more second interrupt controllers 108 may include circuitry for gathering and storing other information, such as priority, interrupt source address, timer information and the like, for handling the respective interrupt which can be provided or read respectively by the first central processing circuitry 102 and the one or more second central processing circuitries 106.

The first comparator 110 may compare an output from the first central processing circuitry 102 with an output from the one or more second central processing circuitries 106. The one or more second comparators 112 may compare the output from the first central processing circuitry 102 with the output from the one or more second central processing circuitries 106. The comparison may allow monitoring of the outputs to detect any discrepancies or errors that may occur during the execution of the set of instructions by the first central processing circuitry 102 and the one or more second central processing circuitries 106.

The at least one logic gate 114 may receive output signals from the first comparator 110 and the one or more second comparators 112 to trigger a fault signal. In one or more examples, the at least one logic gate 114 may be an OR gate. If any of the comparisons performed by the first comparator 110, the one or more second comparators 112, or a combination of both, detect a mismatch between the output from the first central processing circuitry 102 and the output from the one or more second central processing circuitries 106, the OR gate may trigger the fault signal. The at least one logic gate 114 may provide fault tolerance to the apparatus 100 by triggering the fault signal even in an event of a malfunction within one or more comparators 110, 112.

The reset controller 116 may be operatively coupled to receive the fault signal from the at least one logic gate 114. The reset controller 116 may transmit a machine check reset signal responsive to the fault signal received from the at least one logic gate 114. The machine check reset signal may trigger a reset of the apparatus 100. The interrupt signal may be received by the first interrupt controller 104 and the one or more second interrupt controllers 108 in response to the machine check reset signal. The interrupt signal may indicate that the fault signal has been triggered by the at least one logic gate 114. The reset controller 116 may transmit the machine check reset signal to all components within the apparatus 100. These components may include the first central processing circuitry 102, the one or more second central processing circuitries 106, the interrupt controllers 104, 108, and any other components that may need the reset upon fault detection.

The error controller 118 may be operatively coupled to receive the fault signal from the at least one logic gate 114. The error controller 118 may transmit an input/output (IO) float signal responsive to the fault signal received from the at least one logic gate 114. The IO float signal may trigger an electrically floating state of one or more IO pins of the apparatus 100. The error controller 118 may facilitate transition of the apparatus 100 into a safe and reliable state by putting the one or more IO pins in the electrically floating state upon fault detection to prevent the IO pins from transmitting or receiving signals. By entering the safe and reliable state, the apparatus 100 may reduce the chance of causing harm by operating when a fault has been detected, which may increase safety in applications such as automotive, industrial controls, medical devices, aerospace systems and defense systems.

The error injection circuit 120 may be operatively coupled to the one or more second comparators 112 to selectively inject errors to modify or replace the output signals of the one or more second comparators 112 to test the fault signal. In one or more examples, the error injection circuit 120 may be employed to insert an error within the one or more second comparators 112 such that one or more of the output from the first central processing circuitry 102 and the output from the one or more second central processing circuitries 106 received by the one or more second comparators 112 are altered. Because one or more of the output of the first central processing circuitry 102 and the output from the one or more second central processing circuitries 106 is altered, the outputs of the first comparator 110 and the one or more second comparators 112 will not match if the comparators 110, 112 are functioning properly, which would trigger a fault signal from the at least one logic gate 114. Therefore, the error injection circuit 120 may be used to determine whether the first comparator 110, the one or more second comparators 112, and the at least one logic gate 114 are functioning properly. The error injection circuit 120 may be implemented with hardware-based functional safety. The error injection circuit 120 may be executed during startup or power-off, or even on a request of an administrator.

The apparatus 100 may achieve the fault detection and implementation of the safe and reliable state using heterogeneous redundancy, by employing the one or more second central processing circuitries 106, the one or more second interrupt controllers 108, and the one or more second comparators 112. The heterogeneous redundancy may reduce the risk of a single point failure within the safety-focused application. The apparatus 100 may reduce a Fault detection time interval (FDTI) under 1 millisecond.

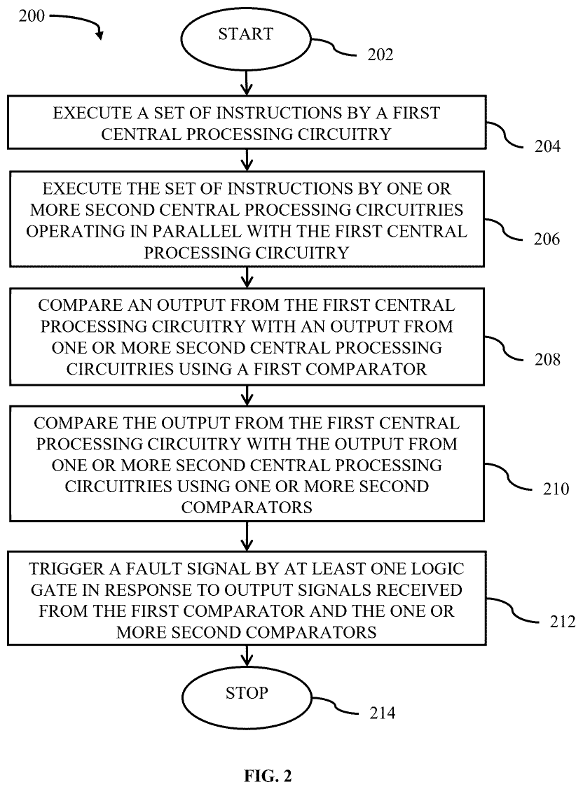

FIG. 2 shows a flowchart 200 illustrating a method for fault detection using an apparatus for detecting faults in a dual core lockstep microcontroller according to one or more examples. It may be noted that in order to explain the method operations of the flowchart 200, references will be made to the elements explained in FIG. 1.

The flowchart 200 starts at operation 202. At operation 204, the method may include executing the set of instructions by the first central processing circuitry 102. At operation 206, the method may include executing the set of instructions by the one or more second central processing circuitries 106 operating in parallel with the first central processing circuitry 102. At operation 208, the method may include comparing the output from the first central processing circuitry 102 with the output from the one or more central processing circuitries 106 using the first comparator 110. At operation 210, the method may include comparing the output from the first central processing circuitry 102 with the output from the one or more second central processing circuitries 106 using the one or more second comparators 112. At operation 212, the method may include triggering the fault signal by the at least one logic gate 114 in response to output signals received from the first comparator 110 and the one or more second comparators 112. According to various examples, the operation 212 may include generating a machine check reset signal in response to the fault signal to reset the apparatus 100. An interrupt signal may be generated in response to the machine check reset signal, which may be received by the first interrupt controller 104 and one or more second interrupt controllers 108 to trigger one or more interrupts. According to various examples, the operation 212 may include generating an IO float signal in response to the fault signal, which may cause one or more IO pins of apparatus 100 to enter a floating state.

The flowchart 200 terminates at operation 214. It may be noted that the flowchart 200 is explained to have above stated process operations; however, those skilled in the art would appreciate that the flowchart 200 may have more/less number of process operations which may enable all the above stated embodiments of the present disclosure.

Various examples have been disclosed herein, in connection with the above description and the drawings. It will be understood that it would be unduly repetitious to literally describe and illustrate every combination and subcombination of these examples. Accordingly, all examples can be combined in any way and/or combination, and the present specification, including the drawings, shall be construed to constitute a complete written description of all combinations and subcombinations of these examples herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. An apparatus for fault detection in a dual core lockstep microcontroller, the apparatus comprising:
a first central processing circuitry to execute a set of instructions;
one or more second central processing circuitries operating in parallel with the first central processing circuitry to execute the set of instructions;
a first comparator to compare an output from the first central processing circuitry with an output from the one or more second central processing circuitries;
one or more second comparators to compare the output from the first central processing circuitry with the output from the one or more second central processing circuitries; and
at least one logic gate to receive output signals from the first comparator and the one or more second comparators to trigger a fault signal based on the received output signals.

2. The apparatus of claim 1, comprising:
a reset controller operatively coupled to receive the fault signal from the at least one logic gate;
wherein the reset controller is to transmit a machine check reset signal responsive to the fault signal received from the at least one logic gate to trigger a reset of the apparatus.

3. The apparatus of claim 1, comprising:
an error controller operatively coupled to receive the fault signal from the at least one logic gate;
wherein the error controller is to transmit an input/output (IO) float signal responsive to the fault signal received from the at least one logic gate to trigger an electrically floating state of one or more IO pins of the apparatus.

4. The apparatus of claim 1, comprising an error injection circuit operatively coupled to at least one of the one or more second comparators to selectively inject errors to modify or replace one or more of the output signals of the one or more second comparators to test the fault signal.

5. The apparatus of claim 1, wherein the at least one logic gate is an OR gate.

6. The apparatus of claim 2, wherein the first central processing circuitry comprises a first interrupt controller to receive an interrupt signal;
wherein the one or more second central processing circuitries comprise one or more second interrupt controllers to receive the interrupt signal; and
wherein the interrupt signal is received by the first interrupt controller and the one or more second interrupt controllers in response to the machine check reset signal to indicate that the fault signal has been triggered by the at least one logic gate.

7. A method for fault detection in a dual core lockstep microcontroller, the method comprising:
executing a set of instructions by a first central processing circuitry;
executing the set of instructions by one or more second central processing circuitries operating in parallel with the first central processing circuitry;
comparing an output from the first central processing circuitry with an output from one or more second central processing circuitries using a first comparator;
comparing the output from the first central processing circuitry with the output from the one or more second central processing circuitries using one or more second comparators; and
triggering, by at least one logic gate, a fault signal in response to output signals received from the first comparator and the one or more second comparators.

8. The method of claim 7, comprising transmitting, by a reset controller, a machine check reset signal in response to the fault signal received from the at least one logic gate to trigger a reset of the dual core lockstep microcontroller.

9. The method of claim 7, comprising transmitting, by an error controller, an input/output (IO) float signal in response to the fault signal received from the at least one logic gate to trigger an electrically floating state of one or more IO pins of the dual core lockstep microcontroller.

10. The method of claim 7, comprising selectively injecting, by an error injection circuit, errors to modify or replace one or more of the output signals of the one or more second comparators to test the fault signal.

11. The method of claim 7, wherein the at least one logic gate is an OR gate.

12. The method of claim 8, comprising receiving an interrupt signal by one or more of a first interrupt controller of the first central processing circuitry and one or more second interrupt controllers of the one or more second central processing circuitries in response to the machine check reset signal to indicate that the fault signal has been triggered by the at least one logic gate.

13. An apparatus for fault detection in a dual core lockstep microcontroller, the apparatus comprising:
a first central processing circuitry to execute a set of instructions;
one or more second central processing circuitries operating in parallel with the first central processing circuitry to execute the set of instructions;
a first comparator to compare an output from the first central processing circuitry with an output from the one or more second central processing circuitries;
one or more second comparators to compare the output from the first central processing circuitry with the output from the one or more second central processing circuitries;
at least one logic gate to receive output signals from the first comparator and the one or more second comparators to trigger a fault signal based on the received output signals;
a reset controller operatively coupled to receive the fault signal from the at least one logic gate, and to transmit a machine check reset signal responsive to the fault signal received from the at least one logic gate to trigger a reset of the apparatus; and
an error controller operatively coupled to receive the fault signal from the at least one logic gate, and to transmit an input/output (IO) float signal responsive to the fault signal received from the at least one logic gate to trigger an electrically floating state of one or more IO pins of the apparatus.

14. The apparatus of claim 13, comprising an error injection circuit operatively coupled to at least one of the one or more second comparators to selectively inject errors to modify or replace one or more of the output signals of the one or more second comparators to test the fault signal.

15. The apparatus of claim 13, wherein the at least one logic gate is an OR gate.

16. The apparatus of claim 13, wherein the first central processing circuitry comprises a first interrupt controller to receive an interrupt signal;
wherein the one or more second central processing circuitries comprise one or more second interrupt controllers to receive the interrupt signal; and
wherein the interrupt signal is received by the first interrupt controller and the one or more second interrupt controllers in response to the machine check reset signal to indicate that the fault signal has been triggered by the at least one logic gate.
